(19) United States
(12) Patent Application Publication
(10) Pub. No.: US 2017/0245373 A1
(43) Pub. Date: Aug. 24, 2017

(54) METHOD OF MANUFACTURING ELECTRONIC UNIT

(71) Applicant: DENSO CORPORATION, Kariya-city (JP)

(72) Inventors: Akito IWAMA, Kariya-city (JP); Shinichi AWANO, Kariya-city (JP); Seiji TACHIBANA, Kariya-city (JP)

(21) Appl. No.: 15/434,466

(22) Filed: Feb. 16, 2017

(30) Foreign Application Priority Data
Feb. 19, 2016 (JP) 2016-029735

(51) Int. Cl. H05K 3/22; B05D 5/00; H05K 1/02

(52) U.S. Cl. CPC H05K 3/22; H05K 1/0203; B05D 5/00; H05K 2201/06; H05K 2203/0126

(57) ABSTRACT

There is provided a method of manufacturing an electronic unit that includes an electronic component having a rectangular plate shape and generating heat during operation, and a heat dissipation gel covering the electronic component. The method includes a side surface coating step of coating opposite two side surfaces of four side surfaces of the electronic component with the heat dissipation gel by discharging the heat dissipation gel from a flat-shaped opening of a nozzle, and a top surface coating step of coating a top surface of the electronic component by discharging the heat dissipation gel from the opening of the nozzle after completion of the side surface coating step.

This application claims priority to Japanese Patent Application No. 2016-029735 filed on Feb. 19, 2016, the entire contents of which are hereby incorporated by reference.

### BACKGROUND OF THE INVENTION

1. Field of the Invention

The present invention relates to an electronic unit manufacturing method.

2. Description of Related Art

In recent years, there is a demand for mounting electronic components such as MOS devices on a single substrate of an electronic unit for driving an actuator to make it possible to downsize the actuator. The electronic components generate heat when they are in operation. It is known to coat the electronic components with heat dissipating gel for dissipating the heat of the electronic components through the heat dissipating gel and a radiator.

To dissipate heat through heat dissipating gel, it is important to prevent formation of voids in the heat dissipating gel as much as possible. Japanese Patent Application Laid-open No. H10-50742 describes an electronic unit manufacturing method in which heat dissipating gel is discharged from a nozzle having a small-diameter opening to be coated on a substrate and side surfaces and a top surface of an electronic component while moving the nozzle spirally from the periphery to the center of the electronic component to suppress formation of voids in the discharged heat dissipating gel.

However, in the above conventional method, since the heat dissipating gel is discharged in a thin line from the small-diameter opening of the nozzle, different portions of the heat dissipating gel discharged from the small-diameter opening of the nozzle contact frequently at their interfaces. Accordingly, roll-in voids may occur in the discharged heat dissipating gel. In this case, since the heat dissipation properties of the electronic component are deteriorated, it may become difficult to downsize the electronic unit.

Further, in the above conventional method, the discharged heat dissipation gel has a mound shape in which the height at the center is larger than the periphery thereof after the coating is finished. Accordingly, when a radiator such as a heat sink is pressed against the heat dissipation gel being discharged so as to put the heat dissipation gel between the radiator and the electronic component, the heat dissipation gel may spread significantly around the electronic component. Therefore, there is a concern that the downsizing of the electronic unit may be prevented in a case where the coating area of the heat dissipation gel is specified or limited.

In addition, since the heat dissipation gel is discharged from the small-diameter opening of the nozzle while moving the nozzle spirally from the periphery to the center of the electronic component, the coating time is long, causing the manufacturing efficiency to be low and causing the manufacturing cost to be high.

### SUMMARY

An exemplary embodiment provides a method of manufacturing an electronic unit that includes an electronic component having a rectangular plate shape and generating heat during operation, and a heat dissipation gel covering the electronic component, including:
a side surface coating step of coating opposite two side surfaces of four side surfaces of the electronic component with the heat dissipation gel by discharging the heat dissipation gel from a flat-shaped opening of a nozzle; and
a top surface coating step of coating a top surface of the electronic component by discharging the heat dissipation gel from the opening of the nozzle after completion of the side surface coating step.

According to the exemplary embodiment, there is provided a method capable of manufacturing a compact electronic unit including an electronic component having a high heat dissipation property in a short time.

Other advantages and features of the invention will become apparent from the following description including the drawings and claims.

### BRIEF DESCRIPTION OF THE DRAWINGS

In the accompanying drawings:

FIG. 1 is a schematic sectional view of a motor provided with an electronic unit manufactured by a manufacturing method according a first embodiment of the invention;

FIG. 2A is a diagram showing an object to be coated with heat dissipation gel and a coating apparatus as viewed in the x-axis direction in a side surface coating step of the manufacturing method according to the first embodiment of the invention;

FIG. 2B is a diagram showing FIG. 2A as viewed from the arrow A;

FIG. 2C is a diagram showing FIG. 2B as viewed from the arrow C;

FIG. 3A is a diagram showing the object to be coated with heat dissipation gel and the coating apparatus as viewed in the x-axis direction in the side surface coating step of the manufacturing method according to the first embodiment of the invention;

FIG. 3B is a diagram showing FIG. 3A as viewed from the arrow A;

FIG. 3C is a diagram showing FIG. 3B as viewed from the arrow C;

FIG. 4A is a diagram showing the object to be coated with heat dissipation gel and the coating apparatus as viewed in the x-axis direction in the side surface coating step of the manufacturing method according to the first embodiment of the invention;

FIG. 4B is a diagram showing FIG. 4A as viewed from the arrow A;

FIG. 4C is a diagram showing FIG. 4B as viewed from the arrow

FIG. 5A is a diagram showing the object to be coated with heat dissipation gel and the coating apparatus as viewed in the x-axis direction in the side surface coating step of the manufacturing method according to the first embodiment of the invention;

FIG. 5B is a diagram showing FIG. 5A as viewed from the arrow A;

FIG. 5C is a diagram showing FIG. 5B as viewed from the arrow C;

FIG. 6A is a diagram showing the object to be coated with heat dissipation gel and the coating apparatus as viewed in the x-axis direction in the side surface coating step of the manufacturing method according to the first embodiment of the invention;

FIG. 6B is a diagram showing FIG. 6A as viewed from the arrow A;

FIG. 6C is a diagram showing FIG. 6B as viewed from the arrow C;

FIG. 7A is a diagram showing the object to be coated with heat dissipation gel and the coating apparatus as viewed in the x-axis direction in the side surface coating step of the manufacturing method according to the first embodiment of the invention;

FIG. 7B is a diagram showing FIG. 7A as viewed from the arrow A;

FIG. 7C is a diagram showing FIG. 7B as viewed from the arrow C;

FIG. 8A is a diagram showing the object to be coated with heat dissipation gel and the coating apparatus as viewed in the x-direction in a top surface coating step of the manufacturing method according to the first embodiment of the invention;

FIG. 8B is a diagram showing FIG. 8A as viewed from the arrow A;

FIG. 8C is a diagram showing FIG. 8B as viewed from the arrow C;

FIG. 9A is a diagram showing the object to be coated with heat dissipation gel and the coating apparatus as viewed in the x-axis direction in the top surface coating step of the manufacturing method according to the first embodiment of the invention;

FIG. 9B is a diagram showing FIG. 9A as viewed from the arrow A;

FIG. 9C is a diagram showing FIG. 9B as viewed from the arrow C;

FIG. 10A is a diagram showing the object to be coated with heat dissipation gel and the coating apparatus as viewed in the x-axis direction in the top surface coating step of the manufacturing method according to the first embodiment of the invention;

FIG. 10B is a diagram showing FIG. 10A as viewed from the arrow A;

FIG. 10C is a diagram showing FIG. 10B as viewed from the arrow C;

FIG. 11A is a diagram showing the object to be coated with heat dissipation gel and the coating apparatus as viewed in the x-axis direction in the top surface coating step of the manufacturing method according to the first embodiment of the invention;

FIG. 11B is a diagram showing FIG. 11A as viewed from the arrow A;

FIG. 11C is a diagram showing FIG. 11B as viewed from the arrow C;

FIG. 12A is a diagram showing the object to be coated with heat dissipation gel and the coating apparatus as viewed in the x-axis direction in the top surface coating step of the manufacturing method according to the first embodiment of the invention;

FIG. 12B is a diagram showing FIG. 12A as viewed from the arrow A;

FIG. 12C is a diagram showing FIG. 12B as viewed from the arrow C;

FIG. 13A is a diagram showing the object to be coated with heat dissipation gel and the coating apparatus as viewed in the x-axis direction in the top surface coating step of the manufacturing method according to the first embodiment of the invention;

FIG. 13B is a diagram showing FIG. 13A as viewed from the arrow A;

FIG. 13C is a diagram showing FIG. 13B as viewed from the arrow C;

FIG. 14A is a diagram showing the object to be coated with heat dissipation gel and the coating apparatus as viewed in the x-axis direction in the top surface coating step of the manufacturing method according to the first embodiment of the invention;

FIG. 14B is a diagram showing FIG. 14A as viewed from the arrow A;

FIG. 14C is a diagram showing FIG. 14B as viewed from the arrow C;

FIG. 15A is a diagram showing the object to be coated as viewed in the x-axis direction after completion of the top surface coating step of the manufacturing method according to the first embodiment of the invention;

FIG. 15B is a diagram showing FIG. 15A as viewed from the arrow A;

FIG. 15C is a diagram showing FIG. 145 as viewed from the arrow C;

FIG. 16A is a diagram showing the object to be coated and the coating apparatus as viewed in the x-axis direction in a radiator pressing step of the manufacturing method according to the first embodiment of the invention;

FIG. 16B is a diagram showing FIG. 16A as viewed from the arrow A;

FIG. 16C is a diagram showing FIG. 16B as viewed from the arrow C;

FIG. 17A is a diagram showing an object to be coated with heat dissipation gel and a coating apparatus as viewed in the x-axis direction in a side surface coating step of the manufacturing method according to a second embodiment of the invention;

FIG. 17B is a diagram showing FIG. 17A as viewed from the arrow A;

FIG. 17C is a diagram showing FIG. 17B as viewed from the arrow C;

FIG. 18A is a diagram showing an object to be coated with heat dissipation gel and a coating apparatus as viewed in the x-axis direction in a side surface coating step of the manufacturing method according to a third embodiment of the invention; and

FIG. 18B is a diagram showing FIG. 18A as viewed from the arrow.

### PREFERRED EMBODIMENTS OF THE INVENTION

### First Embodiment

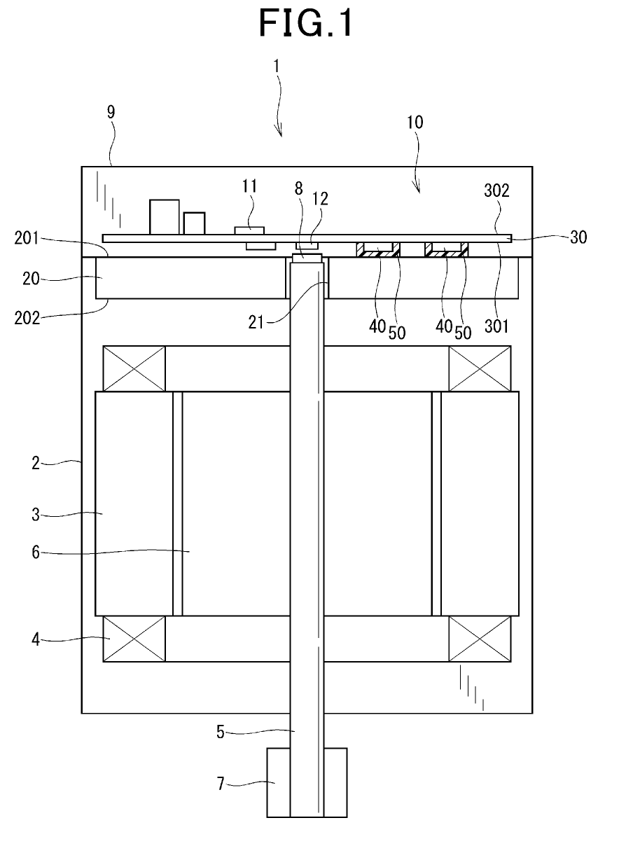

FIG. 1 shows a motor 1 including an electronic unit 10 to be manufactured by a manufacturing method according to a first embodiment of the invention. The motor 1 is used for an electric power steering apparatus, for example. The motor 1 includes a case 2, a stator 3, a winding 4, a shaft 5, a rotor 6, a pulley 7, a magnet 8, the electronic unit 10 and a cover 9.

The case 2 is made of metal in a bottomed cylindrical shape. The stator 3 is made of metal such as steel in an annular shape and fixed to the inner wall of the case 2. The winding 4 is made of metal such as copper in a wire shape and wound on the stator 3. The shaft 5 is made of metal in a stick shape and rotatably supported by the case 2. The shaft 5 is disposed such that its one end projects to the outside from the bottom of the case 2.

The rotor 6 is made of metal such as steel in a cylindrical shape and provided integrally in the shaft 5 such that its inner wall fits the outer wall of the shaft 5. Accordingly, the rotor 6 can rotate together with the shaft 5. A not shown magnet is provided in the outer wall of the rotor 6 so as to be opposite to the inner wall of the stator 3. The pulley 7 is disposed at one end of the shaft 5. The magnet 8 is fitted to the other end of the shaft 5. Accordingly, the pulley 7 and the magnet 8 can rotate together with the shaft 5. The electronic unit 10 is disposed at the opening of the case 2. The cover 9, which covers the electronic unit 10, is disposed in the case 2 so as to close the opening of the case 2. The electronic unit 10 includes a heat sink 20 as a radiator, a substrate 30, electronic components 40, a microcomputer 11, a rotation angle sensor 12 and heat dissipation gel 50. The electronic unit 10 controls electric power supplied to the winding 4 to control the rotation of the rotor 6.

The motor 1 is a mechanically/electrically-integrated motor.

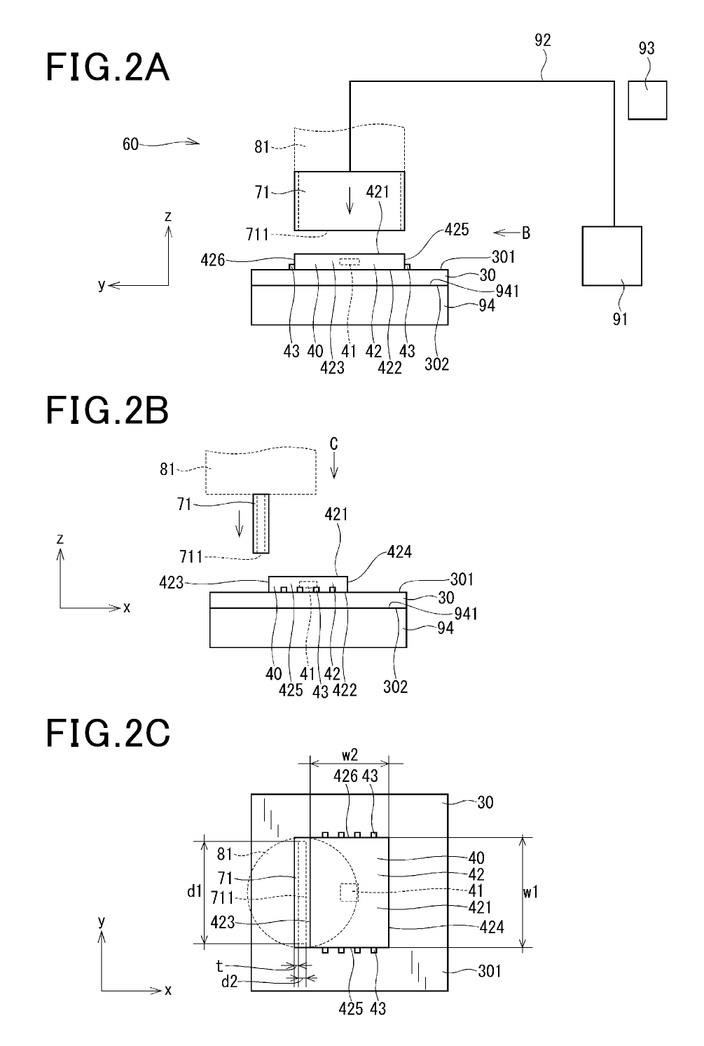

The heat sink 20 is made of metal such as aluminum to have a plate shape, and disposed so as to close the opening of the case 2. The heat sink 20 is formed with a hole 21 at its center. The other end of the shaft 5 is located in the hole 21. The substrate 30 is disposed on the side of one surface 201 (first surface 201 hereinafter) of the heat sink 20, that is, disposed on the side opposite the stator 3. One surface 301 (first surface 301 hereinafter) of the substrate 30 is opposite the first surface 201 of the heat sink 20. The electronic components 40 are mounted on the first surface 301 of the substrate 30. As shown in FIG. 2, each electronic component 40 includes an element 41, a sealing body 42 and terminals 43.

The element 41 is a switching element such as a MOS-FET. The sealing body 42 is made of resin such as epoxy resign in a rectangular plate shape. The sealing body 42 covers the whole of the element 41. The sealing body 42 includes a top surface 421, a bottom, surface 422, four side surfaces 423, 424, 425 and 426. The side surfaces 423 and 424 are opposite to each other. The side surfaces 425 and 426 are opposite to each other.

The longitudinal length (the length in the longitudinal direction) of the side surfaces 423 and 424, that is, the distance between the side surface 425 and the side surface 426 is w1. The longitudinal length of the side surfaces 425 and 426, that is, the distance between the side surface 423 and the side surface 424 is w2. The length w1 is greater than the length w2. Accordingly, the top surface 421 and the bottom surface 422 have a rectangular shape.

The terminals 43 are made of conductive material such as iron-nickel alloy or copper. Each terminal 43 is embedded in the sealing body 42 such that one end thereof is exposed from the side surface 425 or 426. A part of each terminal 43 is eclectically connected to the element 41. Another part of each terminal 43 is solder-connected to a printed wire on the first surface 301 of the substrate 30.

As shown in FIG. 1, the microcomputer 11 is mounted on the second surface 302 of the substrate 30. The microcomputer 11 controls the operation of the element 41 of each electronic component 40 to control electric power supplied to the winding 4. Accordingly, the microcomputer 11 can control the rotation of the rotor 6, that is, the rotation of the motor 1.

The rotation angle sensor 12 is mounted on the first surface 301 of the substrate 30 so as to be located at a position opposite the magnet 8. The rotation angle sensor 12 detects a. rotational position of the rotor 6 by detecting the flux of the rotating magnet 8, and transmits a signal indicating the detected position to the microcomputer 11. The microcomputer 11 controls the rotation of the rotor 6 based on the rotation angle of the rotor 6 detected by the rotation angle sensor 12, the signal transmitted from a torque sensor fitted to the steering shaft and a signal indicating a vehicle speed.

When the rotor 6 rotates, a torque is outputted from the pulley 7 of the shaft 5. This torque is inputted to a not shown rack gear to assist. the steering operation of a vehicle driver. When the motor 1 rotates, that is, when the electronic components 40 operate, a large current flows to each of them, as a result of which the electronic components 40 generate heat. The heat dissipation gel 50 includes silicone resin as base material. The heat dissipation gel 50 contains granular filler made of aluminum oxide or the like.

The heat dissipation gel 50 is disposed between each electronic component 40 and the first surface 201 of the heat sink 20. The heat dissipation gel 50 is in contact with the top surface 421, the side surfaces 423, 424, 425 and 426 of the sealing body 42, the first surface 301 of the substrate 30 and the first surface 210 of the heat sink 20. The heat generated by the electronic component 40 while it operates is transmitted to the heat sink 20 to be dissipated.

Next, a method of manufacturing the electronic unit 10 is explained. This method includes a side surface coating step and a top surface coating step. In the side surface coating step and the top surface coating step, each electronic component 40 and the substrate 30 are coated with the heat dissipation gel 50 using a coating apparatus 60. As shown in FIGS. 2A to 2C, the coating apparatus 60 includes a nozzle 71, a driving section 81, a feed section 91, a pipe 92, a control section 93 and a base 94.

The nozzle 71 is made of metal in a cylindrical shape. The nozzle 71 is formed with an opening 711 at its one end surface (the first end surface hereinafter). As shown in FIG. 2C, the opening 711 has a flat rectangular shape. The longitudinal length d1 of the opening 711 is longer than the transverse length d2 of the opening 711. The length d1 is 10 to 15 times the length d2. That is, the nozzle 71 is the so-called flat tip nozzle. Accordingly, the heat dissipation gel 50 discharged from the opening 711 has a band shape. The transverse length d2 is twice or more the plate thickness t of an end part on the side of the opening 711 of nozzle 71. In this embodiment, the length d2 is 2 mm, and the thickness t is 1 mm. The width in the longitudinal direction of the end part on the side of the opening 711 of the nozzle 71 is equal to the longitudinal length of the side surfaces 423 and 424 of the sealing body 42, that is, equal to the distance w1 between the side surface 425 and the side surface 426. In the following description, x-, y- and z-axis directions are defined such that the z-axis direction corresponds to the vertical direction, and the x-y plane corresponds to the horizontal plane. The driving section 81 is capable of driving the nozzle 71 in all of the x-, y- and z-axis directions relative to the substrate 30 and the electronic component 40 which are coating objects.

The feed section 91 stores therein the heat dissipation gel 50. The pipe 92 connects between the feed section 91 and the nozzle 71. The feed section 91 is capable of sending the heat dissipation gel 50 to the inside of the nozzle 71 through the pipe 92 so that the heat dissipation gel 50 can be discharged from the opening 711 of the nozzle 71.

The control section 93 is comprised of a microcomputer including a CPU, a memory storage such as ROM and RAM, and an I/O interface. The control section 93 controls the operations of the driving section 81 and the feed section 91 in accordance with programs stored in the ROM.

The control section 93 is capable of controlling the operation of the driving section 81 to change the position of the nozzle 71 relative to the electronic component 40 and the substrate 30. Also, the control section 93 is capable of controlling the amount of the heat dissipation gel 50 sent from the feed section 91 to control the amount of the heat dissipation gel 50 discharged from the opening 711 of the nozzle 71. The base 94 has a plane 941 parallel to the x-y plane.

The method of manufacturing the electronic unit 10 includes a component mounting step to be performed before the side surface coating step and the top surface coating step. In the component mounting step, the electronic component 40 is placed at predetermined positions such that the bottom surface 422 of the sealing body 42 is opposite to the first surface 301 of the substrate 30. Then, the terminals 43 of the electronic component 40 are soldered to a printed wire of the substrate 30.

Next, the side surface coating step and the top surface coating step are explained in detail. As shown in FIG. 2A, the substrate 30 on which the electronic component 40 has been mounted is placed on the plane 941 of the base 94. At this time, the second surface 302 of the substrate 30 abuts against the plane 941, the side surfaces 423 and 424 of the sealing body 42 are parallel to the y-z plane, and the side surfaces 425 and 426 are parallel to the x-z plane.

The control section 93 controls the driving section 81 such that the longitudinal axis of the opening 711 of the nozzle 71 is parallel to the y-axis, and is located at a position corresponding to the side surface 423. Thereafter, the control section 93 controls the driving section 81 such that the nozzle 71 approaches the substrate 30.

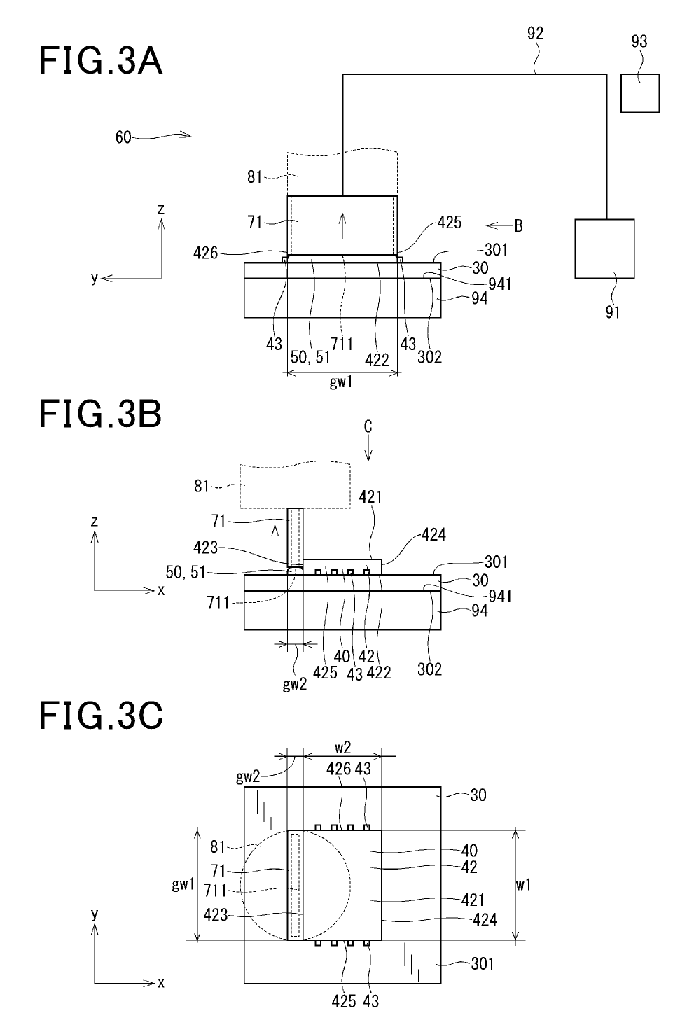

Subsequently, the control section 93 causes the feed section 91 to send the heat dissipation gel 50 to discharge the heat dissipation gel 50 from the opening 711 in a state in which the outer wall of the end portion on the side of the opening 711 of the nozzle 711 abuts against the side surface 423 of the sealing body 42, and the opening of the nozzle 71 is apart from the substrate 30 by a predetermined. distance (see FIGS. 3A. to 3C). The heat. dissipation gel 50 discharged from the opening 711 spreads significantly extending over the opening 711. In this embodiment, the heat dissipation gel 50 spreads as wide as the outer wall of the nozzle 71. Accordingly, the heat dissipation gel 50 is coated on the substrate 30, the boundary between the side surface 423 and the substrate 30, and the side surface 423.

In the following, a portion of the heat dissipation gel 50 which is coated on the side surface 423 is called “the side surface corresponding portion 51” as a matter of convenience. The longitudinal length gw1 of the side surface corresponding portion 51 is equal to the longitudinal length w1 of the side surface 423. The transverse length gw2 of the side surface corresponding portion 51 is equal to the transverse length of the end part on the side of opening 711 of the nozzle 71. The control section 93 causes the nozzle 71 to move in the z-axis direction, that is, causes the nozzle 71 to move away from the substrate 30 while the heat dissipation gel 50 is being discharged from the opening 711 with the outer wall of the nozzle 71 abutting against the side surface 423.

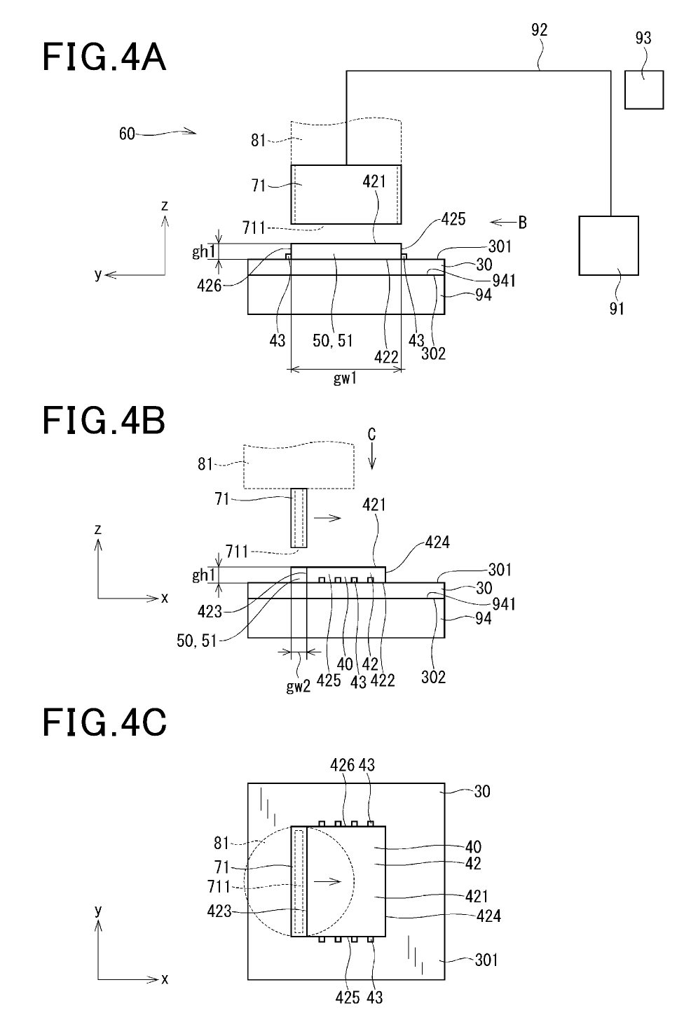

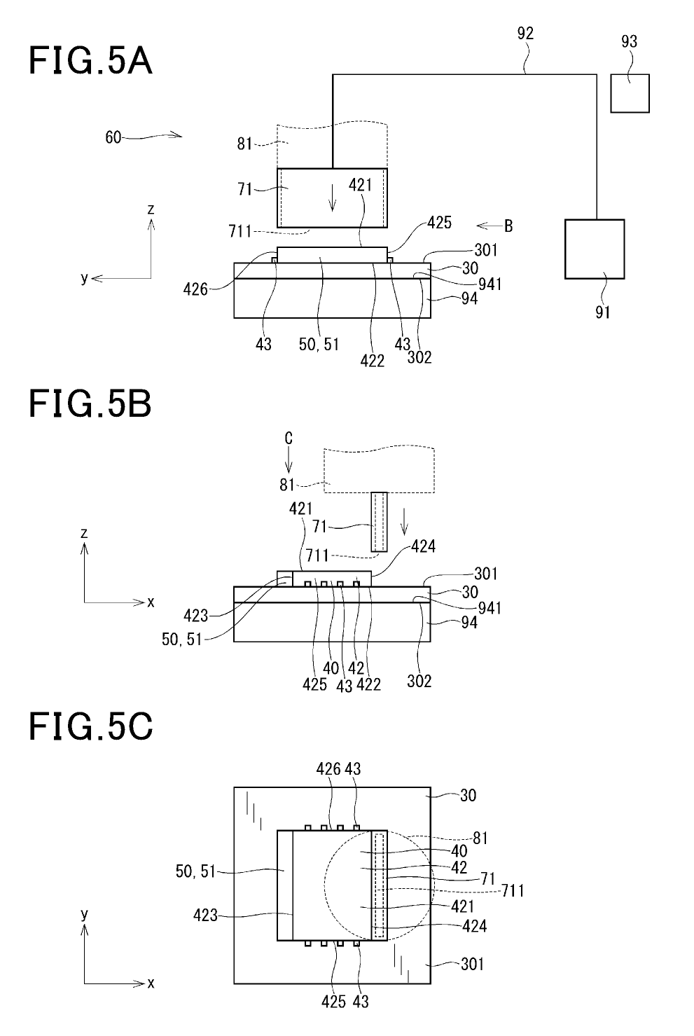

The control section 93 stops the heat dissipation gel 50 from being discharged from the nozzle 71 at a time when the height of the side surface corresponding portion 51 from the substrate 30 becomes equal to the plate thickness of the sealing body 42. As a result, the side surface corresponding portion 51 has a rectangular shape whose longitudinal axis is parallel to the side surface 423 (see FIGS. 4A to 4C). Then, the control section 93 causes the nozzle 71 to move in the x-axis direction. As shown in FIGS. 5A to 5C, the control section 93 controls the driving section 81 such that the nozzle 71 approaches the substrate 30 at a time when there is reached a state in which the longitudinal axis of the opening 711 of the nozzle 71 is parallel to the y-axis and is located at a position corresponding to the side surface 424.

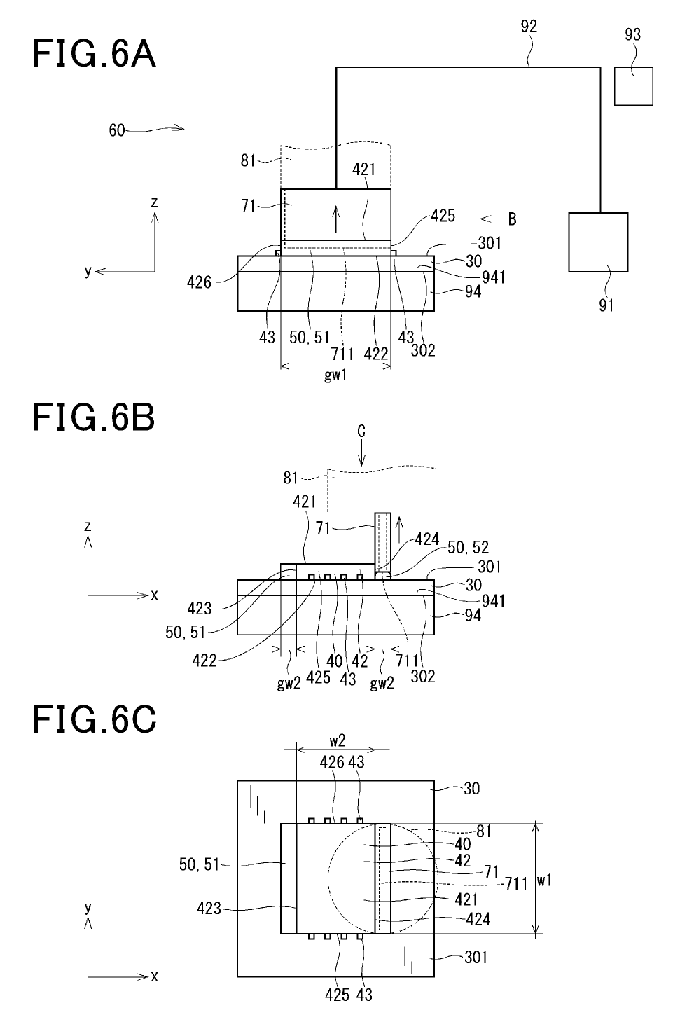

Subsequently, the control section 93 causes the feed section 91 to send the heat dissipation gel 50 for discharging the heat dissipation gel 50 from the opening 711 in a state in which the outer wall of the end part on the side of the opening 711 of the nozzle 711 abuts against the side surface 424 of the sealing body 42, and the opening 711 is away from the substrate 30 by a predetermined distance (see FIGS. 6A to 6C). The heat dissipation gel 50 discharged from the opening 711 spreads significantly extending over the opening 711. Accordingly, the heat dissipation gel 50 is coated on the substrate 30, the boundary between the side surface 424 and the substrate 30, and the side surface 424.

In the following, a portion of the heat dissipation gel 50 that is coated on the side surface 424 is called “the side surface corresponding portion 52” as a matter of convenience. The longitudinal length gw1 of the side surface corresponding portion 52 is equal to the longitudinal length w1 of the side surface 423. The transverse length gw2 of the side surface corresponding portion 52 is equal to the transverse width of the end part on the side of opening 711 of the nozzle 71. The control section 93 causes the nozzle 71 to move in the z-axis direction, that is, causes the nozzle 71 to move away from the substrate 30 while the heat dissipation gel 50 is being discharged from the opening 711 with the outer wall of the nozzle 71 abutting against the side surface 424.

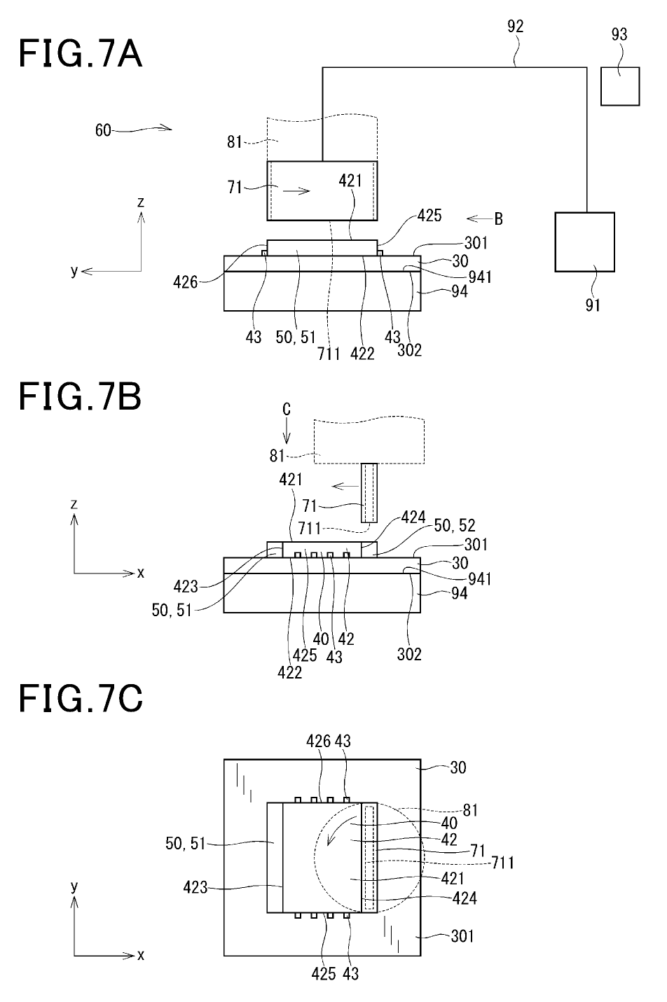

The control section 93 stops the heat dissipation gel 50 from being discharged from the nozzle 71 at a time when the height of the side surface corresponding portion 52 from the substrate 30 becomes approximately equal to the plate thickness of the sealing body 42. As a result, the side surface corresponding portion 52 has a rectangular shape whose longitudinal axis is parallel to the side surface 424 (see FIGS. 7A to 7C). The side surface coating step is finished at this point of time. Thereafter, the control section 93 turns and moves the nozzle 71 such that the longitudinal axis of the opening 711 of the nozzle 71 becomes parallel to the x-axis and the side surface 425.

Next, the top surface coating step is explained. The top surface coating step includes a first other side surface coating step and a second other side surface coating step. In the first other side surface coating step, the heat dissipation gel 50 is coated on the side surface 425. In the second other side surface coating step, the heat dissipation gel 50 is coated on the side surface 426.

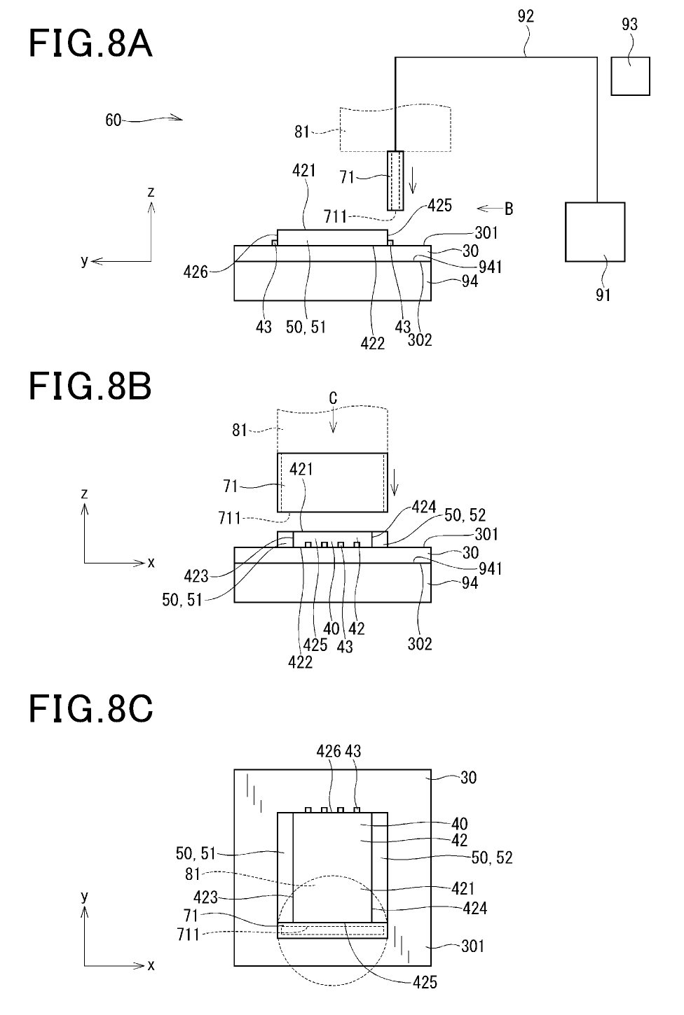

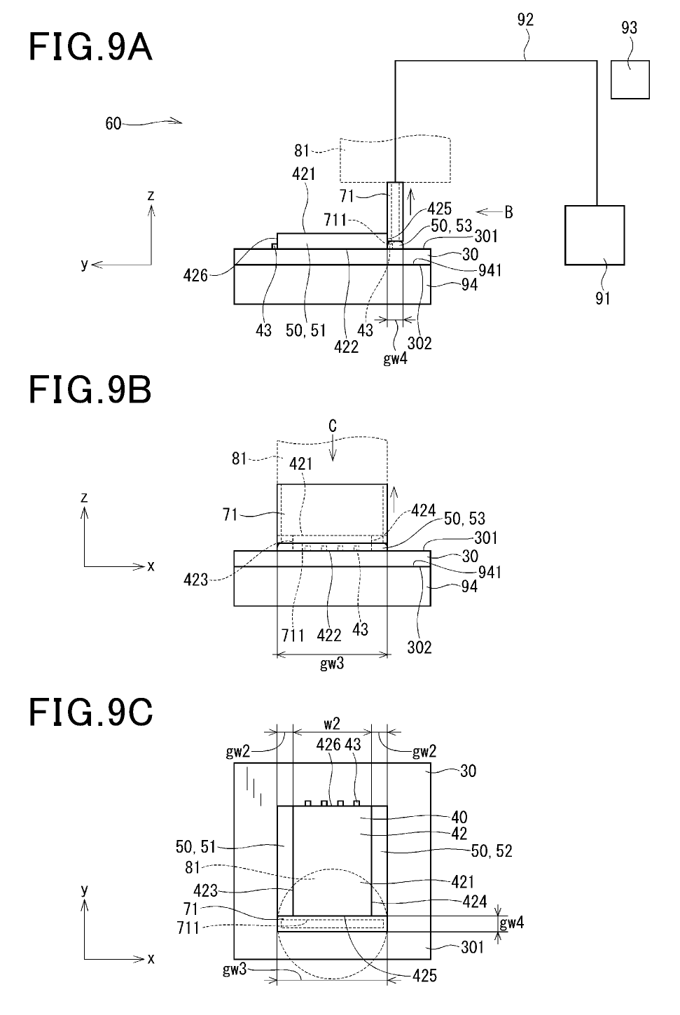

First, the first other side surface coating step is explained. As shown in FIGS. 8A to 8C, the control section 93 controls the driving section 81 such that the nozzle 71 approaches the substrate 30 at a time when there is reached a state in which the longitudinal axis of the opening 711 of the nozzle 71 is parallel to the x-axis and located at a position corresponding to the side surface 425. Subsequently, the control section 93 causes the feed section 91 to send the heat dissipation gel 50 for discharging the heat dissipation gel 50 from the opening 711 in a state in which the outer wall of the end part on the side of the opening 711 of the nozzle 711 abuts against the side surface 425 of the sealing body 42, and the opening 711 is kept separated from the substrate 30 by a predetermined distance (see FIGS. 9A to 9C). The heat dissipation gel 50 discharged from the opening 711 spreads significantly extending over the opening 711. Accordingly, the heat dissipation gel 50 is coated on the substrate 30, the boundary between the side surface 425 and the substrate 30, and the side surface 425.

In the following, a portion of the heat dissipation gel 50 that is coated on the side surface 425 is called “the side surface corresponding portion 53” as a matter of convenience. The longitudinal length gw3 of the side surface corresponding portion 53 is equal to the sum of the longitudinal length w2 of the side surface 425, the transverse length gw2 of the side surface corresponding portion 51 and the transverse length gw2 the side surface corresponding portion 52. The transverse length gw4 of the side surface corresponding portion 53 is equal to the transverse width of the end part on the side of opening 711 of the nozzle 71. That is, in this embodiment, the longitudinal length gw3 of the side surface corresponding portion 53 is equal to the longitudinal length gw1 of the side surface corresponding portions 51 and 52, and the transverse length gw4 of the side surface corresponding portion 53 is equal to the transverse length gw2 of the side surface corresponding portions 51 and 52.

The control section 93 causes the nozzle 71 to move in the z-axis direction, that is, causes the nozzle 71 to move away from the substrate 30 while the heat dissipation gel 50 is being discharged from the opening 711 with the outer wall of the nozzle 71 abutting against the side surface 425. At this time, the side surface corresponding portion 53 and the side surface corresponding portions 51 and 52 are integrated to one another. The first other side surface coating step is finished at this point in time.

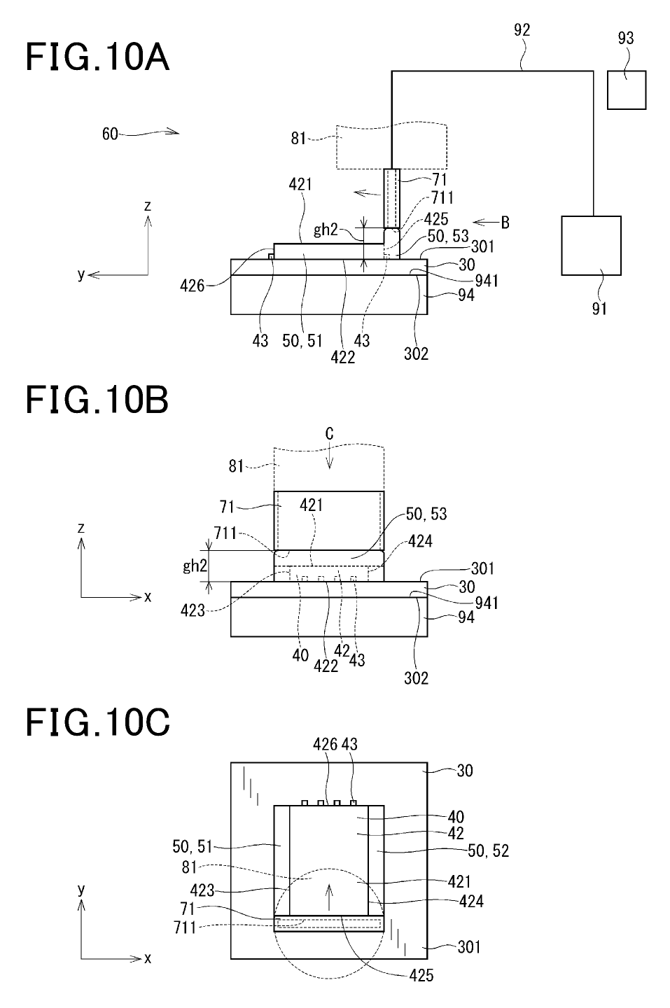

As shown in FIG. 10, when the height of side surface corresponding portion 53 from the substrate 30 becomes approximately twice the plate thickness of the sealing body 42, the control section 93 moves the nozzle 71 in the y-axis direction while moving the opening 711 away from the top surface 421 of the sealing body 42. At that time, the control section 93 gradually increase the amount of the heat dissipation gel 50 being discharged from the opening 711.

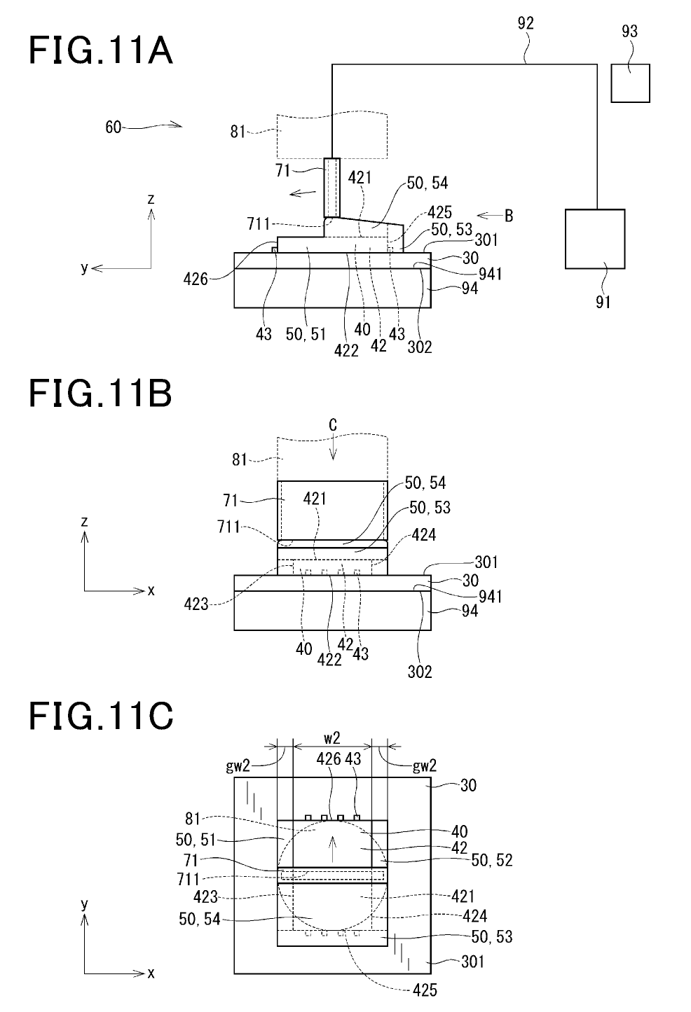

As a result, the heat dissipation gel 50 is coated on the side surface corresponding portions 51 and 52 and the top surface 421 of the sealing body 42 (see FIGS. 11A to 11C). In the following, a portion of the heat dissipation gel 50 that is coated on the top surface 421 and the side surface corresponding portions 51 and 52 is called “the top surface corresponding portion 54” as a matter of convenience. The top surface corresponding portion 54 is integrally connected with the side surface corresponding portion 53.

As shown in FIGS. 11A to 11C, the control section 93 moves the nozzle 71 in the y-axis direction while causing the opening 711 to approach the top surface 421 of the sealing body 42 at a time when the nozzle 71 has moved to the position corresponding to the center of the sealing body 42. At this time, the control section 93 gradually decreases the amount of the heat dissipation gel 50 being discharged from the opening 711. The top surface corresponding portion 54 integrally connects with the side surface connecting parts 51 and 52.

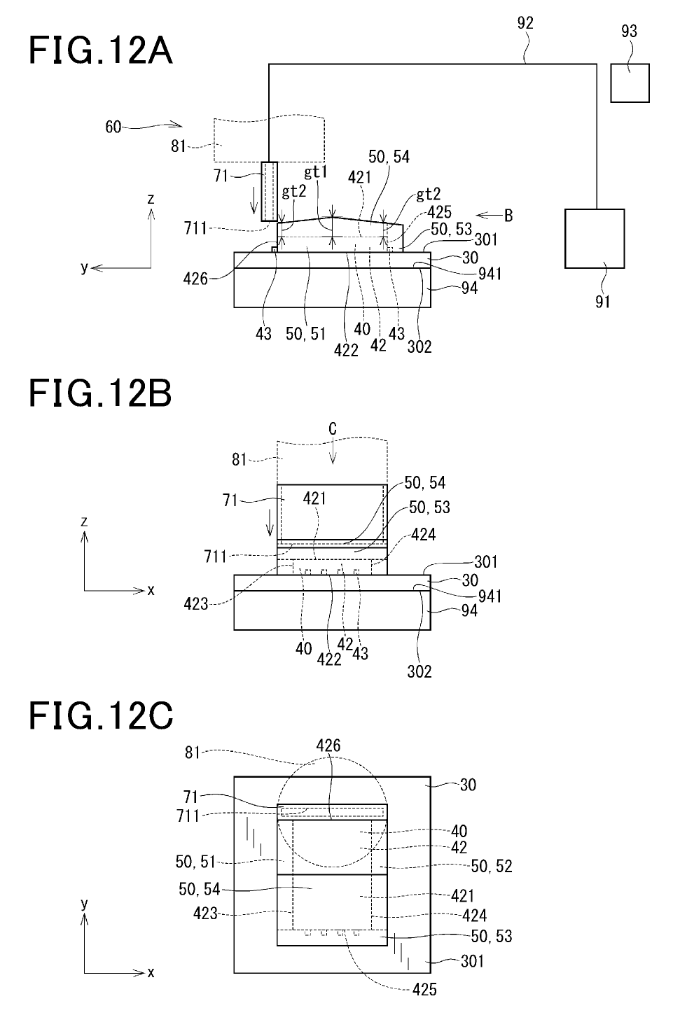

As a result, the thickness gt1 of the top surface corresponding portion 54 at the position corresponding to the center of the sealing body 42 becomes larger than the thickness gt2 of the top surface corresponding portion 54 at the position corresponding to the both ends of the sealing body 42, that is, at the position corresponding to the ends on the sides of the side surface 425 and the side surface 426 (see FIGS. 12A to 12C). Therefore, the top surface corresponding portion 54 has a mound shape in which the center projects upward (see FIG. 12A).

Next, a second other surface coating step is explained. As shown in FIGS. 12A to 12C, the control section 93 controls the driving section 81 such that the nozzle 71 approaches the substrate 30 at a time when there is reached a state in which the longitudinal axis of the opening 711 becomes parallel to the x-axis and located at a position corresponding to the side surface 426.

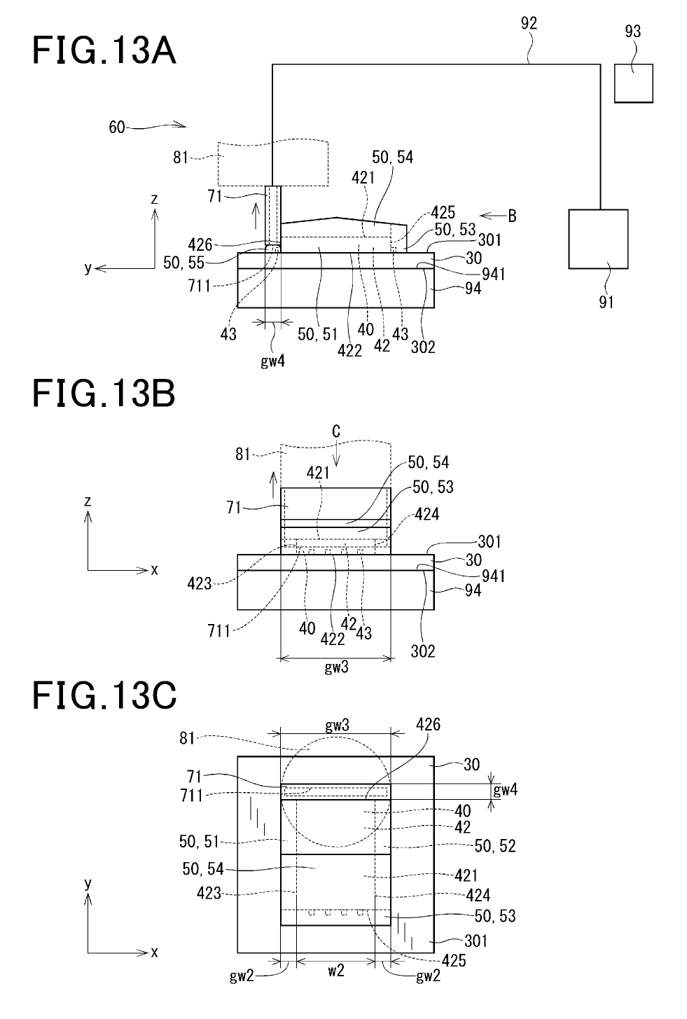

Subsequently, the control section 93 causes the feed section 91 to send the heat dissipation gel 50 for discharging the heat dissipation gel 50 from the opening 711 in a state in which the outer wall of the end part on the side of the opening 711 of the nozzle 71 abuts against the side surface 426 of the sealing body 42, and the opening 711 is away from the substrate 30 by a predetermined distance (see FIGS. 13A to 13C). The heat dissipation gel 50 discharged from the opening 711 spreads significantly extending over the opening 711. Accordingly, the heat dissipation gel 50 is coated on the substrate 30, the boundary between the side surface 426 and the substrate 30, the terminals 43 and the side surface 426.

In the following, a portion of the heat dissipation gel 50 that is coated on the side surface 426 is called “the side surface corresponding portion 55” as a matter of convenience. The longitudinal length gw3 of the side surface corresponding portion 55 is equal to the sum of the longitudinal length w2 of the side surface 426, the transverse length gw2 of the side surface corresponding portion 51 and the transverse length gw2 of the side surface corresponding portion 52. The transverse length gw4 of the side surface corresponding portion 55 is equal to the transverse width of the end part on the side of opening 711 of the nozzle 71. That is, in this embodiment, the longitudinal length gw3 of the side surface corresponding portion 55 is equal to the longitudinal length gw1 of the side surface corresponding portions 51 and 52, and the transverse length gw4 of the side surface corresponding portion 55 is equal to the transverse length gw2 of the side surface corresponding portions 51 and 52.

The control section 93 causes the nozzle 71 to move in the z-axis direction, that is, causes the nozzle 71 to move away from the substrate 30 while the heat dissipation gel 50 is being discharged from the opening 711 with the outer wall of the nozzle 71 abutting against the side surface 426. The side surface corresponding portions 55 and 51 integrally connect with the side surface connecting part 52 and the top surface corresponding portion 54.

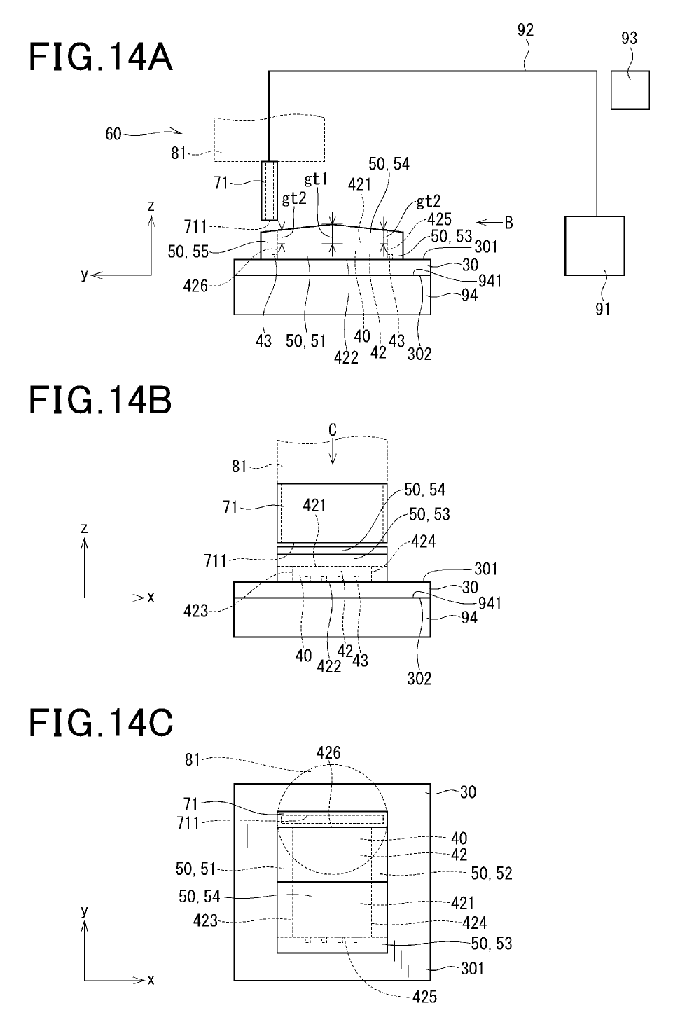

The control section 93 stops the heat dissipation gel 50 from being discharged from the nozzle 71 at a time when the height of the side surface corresponding portion 55 from the substrate 30 becomes equal to approximately twice the plate thickness of the sealing body 42. As a result, the side surface corresponding portion 55 has a rectangular shape whose longitudinal axis is parallel to the side surface 426 (see FIGS. 14A to 14C). The second other side surface coating step and the top surface coating step are finished at this point of time.

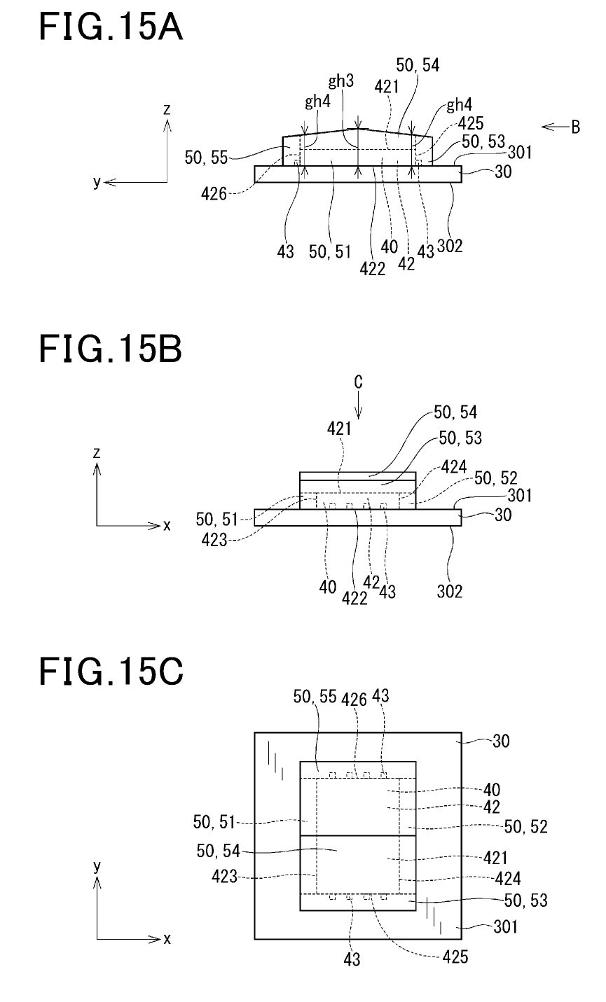

As shown in FIGS. 15A to 15C, after completion of the side surface coating step and the top surface coating step, the electronic component 40 is in a state of being covered by the heat dissipation gel 50. In this state, the heat dissipation gel 50 adheres tightly to the side surfaces 423, 424, 425 and 426 and the top surface 421 of the sealing body 42, the terminals 43, and the first surface 301 of the substrate 30. The height gh3 of the heat dissipation gel 50 from the substrate 30 at the position corresponding to the center of the sealing body 42 is larger than the height gh4 of the heat dissipation gel 50 from the substrate 30 at the position corresponding to the both ends of the sealing body 42, that is, at the position corresponding to the end part on the side of the side surface 425 and the end part on the side of the side surface 126. The heat dissipation gel 50 is coated in a rectangular shape as viewed in the z-axis direction, the area of which is less than 3.5 times the area of the top surface 421 of the sealing body 42 (see FIG. 15C).

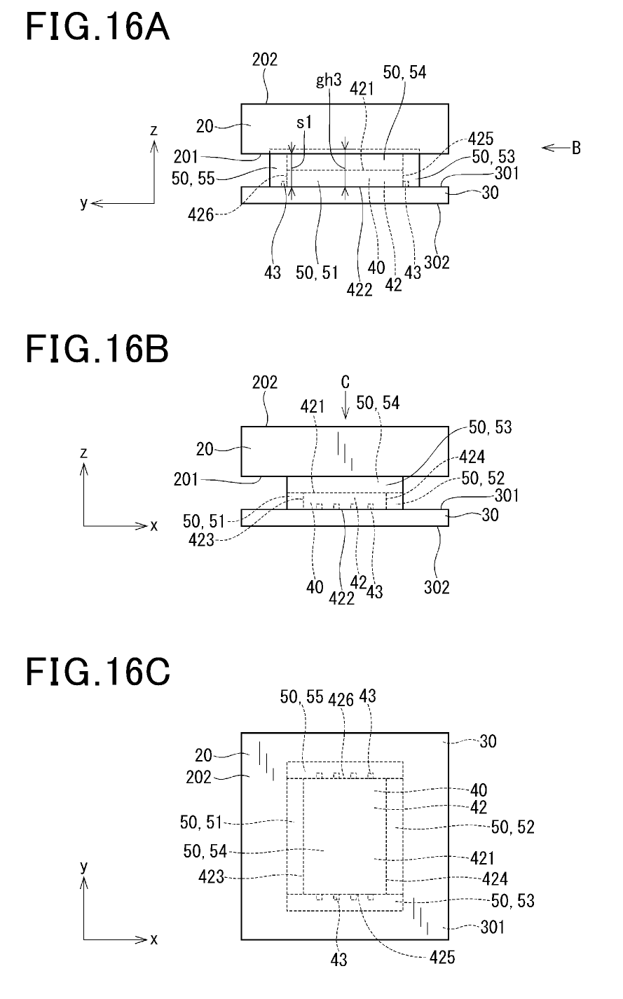

The method of manufacturing the electronic unit 10 also includes a radiator pressing step. The radiator pressing step is explained in the following. As shown in FIGS. 16A to 16C, the heat sink 20 as a radiator pressed against the heat dissipation gel 50 such that the heat sink 20 and the first surface 301 of the substrate 30 relatively approach each other. More specifically the heat sink 20 is pressed against the heat dissipation gel 50 such that the distance s1 between the first surface 201 of the heat sink 20 and the first surface 301 of the substrate 30 becomes smaller than the height of the heat dissipation gel 50 from the substrate 30 at the position corresponding to the center of the sealing body 42. As a result, the portion of the heat dissipation gel 50 corresponding to the center of the sealing body 42 spreads toward the end part on the side of the side surface 425 and the end part on the side of the side surface 426, and accordingly the height of the heat dissipation gel 50 from the substrate 30 becomes equal to the distance s1 between the heat sink 20 and the substrate 30. At this time, the heat dissipation gel 50 adheres tightly to the first surface 201 of the heat sink 20. Since the height of the heat dissipation gel 50 before the heat sink 20 is pressed is larger at the position corresponding to the center of the dealing body 42 than at the both end parts, the heat dissipation gel 50 gradually spreads from the center toward the both end parts while contacting the heat sink 20. Accordingly, it is possible to prevent the formation of voids between the heat dissipation gel 50 and the heat sink 20.

(1) As explained above, the above described method of manufacturing the electronic unit 10 that includes the electronic component 40 having a rectangular plate shape and generating heat during operation and the heat dissipation gel 50 covering the electronic component 40 includes the side surface coating step and the top surface coating step.

In the side surface coating step, the heat dissipation gel 50 is discharged from the opening 711 having a flat rectangular shape of the nozzle 711 to coat the opposite side surfaces 423 and 424 with the heat dissipation gel 50. In the top surface coating step after the side surface coating step, the heat dissipation gel 50 is discharged from the opening 711 to coat the top surface 421 of the electronic component with the heat dissipation gel 50.

In each of the side surface coating step and the top surface coating step, since the opening 711 from which the heat dissipation gel 50 is discharged is flat-shaped, it is possible to prevent different portions of the heat dissipation gel 50 injected from the opening 71 of the nozzle 71 from contacting at their interfaces. Accordingly, it is possible to prevent formation of roll-in voids in the discharged heat dissipation gel 50. As a result, since the heat dissipation property of the electronic component 40 increases, the electronic unit 10 can be formed in a single substrate to thereby downsize the electronic unit 10.

Compared to the prior art in which heat dissipation gel is discharged from a small diameter circular opening of a nozzle while spirally moving the nozzle, the coating time can be reduced according to the above described embodiment because the heat dissipation gel is discharged from the flat opening 711. Therefore, according to the above described manufacturing method, it is possible to manufacture a small-sized. electronic unit including an electronic component having high heat dissipation property in a short time.

(2) In the above described embodiment, the electronic unit 10 further includes the substrate 30 disposed on the side opposite to the top surface 421 of the electronic component 40. In the side surface coating step, the heat dissipation gel 50 is coated on the boundary between the substrate 30 and the opposite side surfaces 423 and 424 (see FIGS. 3A to 3C and 6A to 6C). Accordingly, it is possible to prevent the formation of voids in the boundary between the substrate 30 and the opposite side surfaces 423 and 424. Therefore, the heat dissipation property of the electronic component 40 can be increased.

(3) In the side surface coating step and the top surface coating step, the heat dissipation gel 50 is coated on the boundary between the substrate 30 and all the four side surfaces 423, 224, 425 and 426 of the electronic component 40 (see FIGS. 3A to 3C, 6A to 6C, 9A to 9C and 13A to 13C). Accordingly, it is possible to prevent formation of voids in the boundary between the substrate 30 and the side surfaces 423, 424, 425 and 426 to thereby further increase the heat dissipation property of the electronic component 40.

(4) In the side surface coating step and the top surface coating step, the outer wall of the end part on the side of the opening 711 of the nozzle 71 is caused to abut against the sealing body 42 of the electronic component 40 at the time of coating the heat dissipation gel 50 on the boundary between the substrate 30 and the side surfaces 423, 424, 425 and 426 of the electronic component 40. This makes it possible to maintain the distance between the opening 711 and the boundary approximately the same as the plate thickness of the nozzle 71. As a result, the heat dissipation gel 50 can be coated uniformly on the boundary between the substrate 30 and the side surfaces 423, 424, 425 and 426.

(5) The transverse length d2 of the opening 711 of the nozzle 71 is larger than twice the plate thickness t of the end part on the side of the opening 711 of the nozzle 71 (see FIG. 2C). Accordingly, the heat dissipation gel 50 discharged from the opening 711 spreads significantly extending over the opening 711 until its width becomes approximately the same as the width of the outer wall of the end part on the side of the opening 711 of the nozzle 71.

(6) The longitudinal length d1 of the opening 711 of the nozzle 71 is smaller than the longitudinal length w1 of the opposite side surfaces 423 and 424 (see FIG. 2C).

(7) In the side surface coating step, the heat dissipation gel 50 is discharged from the opening 711 of the nozzle 71 such that its width does not exceed the longitudinal length w1 of the opposite side surfaces 423 and the 424 (see FIGS. 3A to 3C and 6A to 6C). Accordingly, it is possible to prevent the heat dissipation gel 50 from protruding outside a predetermined area at the time of discharging the heat dissipation gel from the opening 711 of the nozzle 71 to coat the side surface 423 or 42 with the heat dissipation gel 50. Therefore, it is possible to downsize a product even if a coating area is limited or specified.

(8) In the top surface coating step, the heat dissipation gel 50 is discharged at a width which is smaller than the sum of the distance w2 between the opposite side surfaces 423 and 424 of the sealing body 42 of the electronic component 40 and the width gw2 of the side surface corresponding portions 51 and 52 (see FIG. 11A to 11C). Accordingly, it is possible to prevent the heat dissipation gel 50 from protruding outside a predetermined area at the time of discharging the heat dissipation gel from the opening 711 of the nozzle 71 to coat the top surface 421 and the side surface corresponding portions 51 and 52. Therefore, it is possible to downsize a product even if a coating area is limited or specified.

(9) In the top surface coating step, the heat dissipation gel 50 is discharged such that the thickness gt1 thereof at the position corresponding to the center of the sealing body 42 of the electronic component 40 is smaller than the thickness gt2 thereof at the position corresponding to the both end parts of the sealing body 42 of the electronic component 40, that is, the end parts on the side of the side surface 425 and the side of the side surface 426 (see FIGS. 12A to 12C). Therefore, the heat dissipation gel 50 gradually spreads from the center toward the both end parts while contacting the heat sink 20 in the radiator pressing step after the top surface coating step. Accordingly, it is possible to prevent the formation of voids between the heat dissipation gel 50 and the heat sink 20, and to dissipate the heat of the electronic component 40 from the heat sink 20 through the heat dissipation gel 50.

### Second Embodiment

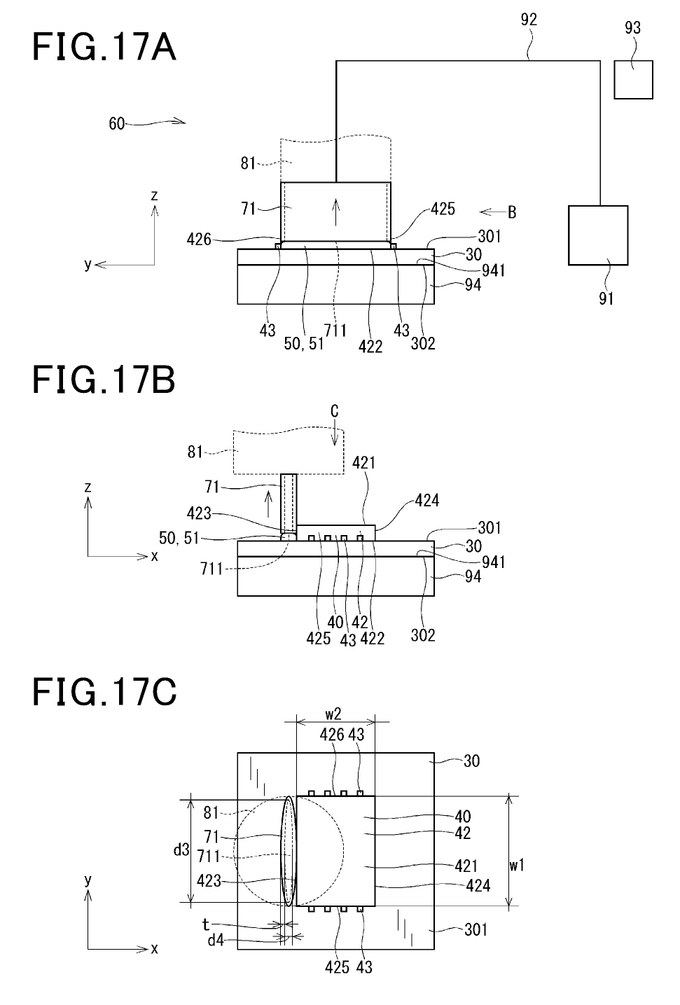

Next, a method of manufacturing the electronic unit 10 according to a second embodiment of the invention is described with reference to FIG. 17A to 17C.

In the second embodiment, the opening 711 of the nozzle 71 has a flat circular shape, that is, an oval shape as shown in FIG. 17C. The opening 711 has a major diameter (a longitudinal length) d3 and a minor diameter (a transverse length) d4 smaller than the major diameter d3. In this embodiment, the longitudinal length d3 is 10 to 15 times larger than the transverse length d4. That is, in this embodiment, the nozzle 71 is the so-called flat nozzle as in the first embodiment. Accordingly, the heat dissipation gel 50 discharged from the opening 711 has a band shape. The nozzle 71 used in this embodiment can be formed by squashing a cylindrical member in the radial direction, for example. The transverse length d4 the opening 711 is larger than twice the plate thickness t of the end part on the side of the opening 71 of the nozzle 71. The longitudinal length d3 of the opening 711 is smaller than the longitudinal length w1 of the opposite side surfaces 423 and 424 (see FIG. 17C).

Except for the above, the second embodiment is the same as the first embodiment. FIGS. 17A to 17C, which corresponds to FIGS. 3A to 3C for the first embodiment, show the coating apparatus 60, the electronic component 40, the substrate 30 and the heat dissipation gel 50 in the side surface coating step.

As explained above, in the second embodiment, the heat dissipation gel 50 is discharged from the flat opening 711 to coat the electronic component 40 and the substrate 30 as in the first embodiment. Like the first embodiment, according to the second embodiment, it is possible to prevent formation of roll-in voids in the heat dissipation gel 50 having been discharged and to reduce the coating time.

### Third Embodiment

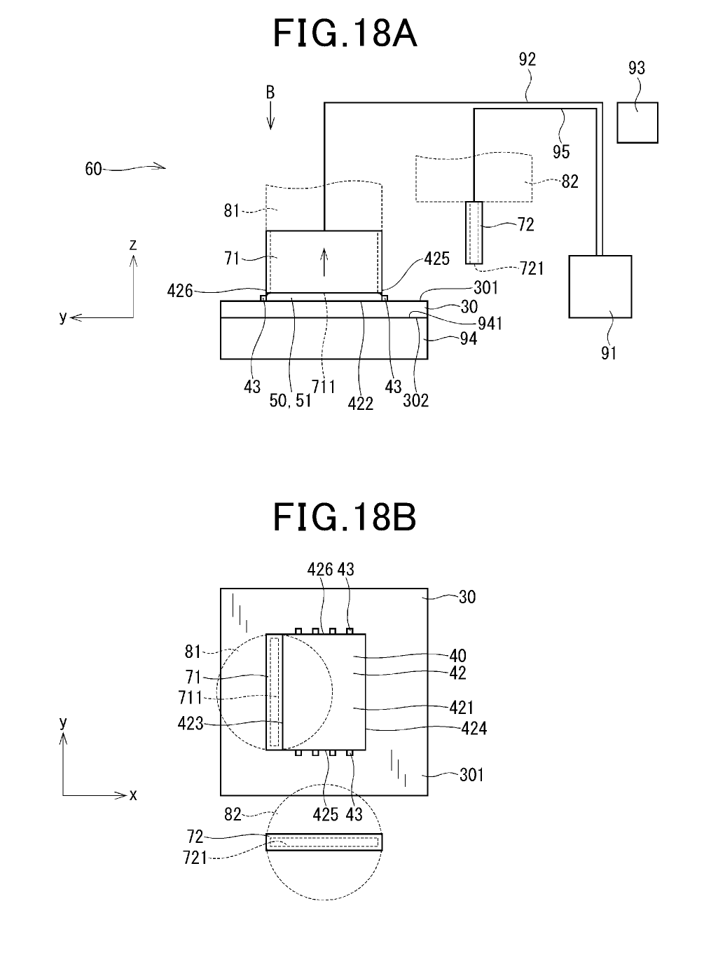

Next, a method of manufacturing the electronic unit 10 according to a third embodiment of the invention is described with reference to FIGS. 18A to 18C. The coating apparatus 60 used in the third embodiment further includes a nozzle 72, a driving section 82 and a pipe 95.

The nozzle 72 is made of metal in a cylindrical shape of a rectangular cross section. The nozzle 72 is formed with an opening 721 at its one end surface. As shown in FIG. 18R, the opening 721 has a flat rectangular shape. Since the opening 721 is the same in structure as the opening 711 of the nozzle 71, detailed explanation of it is omitted here. The driving section 82 is capable of driving the nozzle 72 in all of the x-, y- and z-axis directions relative to the substrate 30 and the electronic component 40 as coating objects.

The pipe 95 connects between the feed section 91 and the nozzle 72. The feed section 91 is capable of sending the heat dissipation gel 50 to the inside of the nozzle 72 through the pipe 95 so that the heat dissipation gel 50 can be discharged from the opening 721 of the nozzle 72.

The control section 93 is capable of controlling the operation of the driving section 82 to change the position of the nozzle 72 relative to the electronic component 40 and the substrate 30. Also, the control section 93 is capable of controlling the amount of the heat dissipation gel 50 sent from, the feed section 91 to control the amount of the heat dissipation gel 50 discharged from the opening 721 of the nozzle 72.

In the third embodiment, the heat dissipation gel 50 is discharged from the nozzle 71 to coat the side surfaces 423 and 424 of the sealing body 42 of the electronic component 40 with the heat dissipation gel 50. In the top surface coating step, the heat dissipation gel 50 is discharged from the nozzle 72 to coat the side surface 425, the top surface 421 and. the side surface 426 of the sealing body 42 with the heat dissipation gel 50. Accordingly, unlike in the first embodiment, it is not necessary to turn the nozzle 71 between the side surface coating step and the top surface coating step. Since the top surface coating step can be started immediately after the side surface coating step is finished, the coating time of the heat dissipation gel 50 can be further reduced.

### Other Embodiments

In the above embodiments, the sealing body 42 of the electronic component 40 is formed in a rectangular plate shape. However, the sealing body 42 of the electronic component 40 may be formed in a square plate shape.

The outer wall of the end part on the side of the openings 711 or 721 may not be caused to abut against the sealing body 42 of the electronic component 40 at the time of coating the heat dissipation gel 50 on the boundary between the substrate 30 and the side surface s 423, 424, 425 and 426 of the sealing body 40. One of the first other surface coating step and the second other surface coating step may be omitted. The opening of the nozzle can have any arbitrary shape as long as it is flat. The ratio of the transverse length of the opening of the nozzle to the plate thickness of the end part on the side of the opening of the nozzle may have any value.

In the above embodiments, the longitudinal length of each of the opening 711 or 712 is 10 to 15 times the transverse length thereof. However, the longitudinal length is not limited thereto. The longitudinal length may be 2 to 10 times the transverse length, for example. The above embodiments are related to manufacturing the electronic unit 10 of the motor 1 for an electric power steering apparatus. It should be noted that the present invention can be used for manufacturing an electronic unit for controlling operation of an electric part of any apparatus.

The above explained preferred embodiments are exemplary of the invention of the present application which is described solely by the claims appended below. It should be understood that modifications of the preferred embodiments may be made as would occur to one of skill in the art.

What is claimed is:

1. A method of manufacturing an electronic unit that includes an electronic component having a rectangular plate shape and generating heat during operation, and a heat dissipation gel covering the electronic component, comprising:
a side surface coating step of coating opposite two side surfaces of four side surfaces of the electronic component with the heat dissipation gel by discharging the heat dissipation gel from a flat-shaped opening of a nozzle; and
a top surface coating step of coating a top surface of the electronic component by discharging the heat dissipation gel from the opening of the nozzle after completion of the side surface coating step.

2. The method according to claim 1, wherein the electronic unit further includes a substrate disposed opposite to the top surface of the electronic component, and the heat dissipation gel is coated on a boundary between the opposite side surfaces and the substrate.

3. The method according to claim 1, wherein the heat dissipation gel is coated on a boundary between the substrate and the four side surfaces of the electronic component in each of the side surface coating step and the top surface coating step.

4. The method according to claim 3, wherein an outer wall of an end part on the side of the opening of the nozzle is caused to abut against the electronic component when the heat dissipation gel is coated on the boundary in each of the side surface coating step and the top surface coating step.

5. The method according to claim 1, wherein a transverse length of the opening is larger than twice a plate thickness of the end part on the side of the opening of the nozzle.

6. The method according to claim 1, wherein a longitudinal length of the opening is smaller than a longitudinal length of the opposite side surfaces.

7. The method according to claim 1, wherein, in the side surface coating step, the heat dissipation gel is discharged from the opening at a width smaller than a longitudinal length of the opposite side surfaces.

8. The method according to claim 1, wherein, in the top surface coating step, the heat dissipation gel is discharged from the opening at a width smaller than the sum of a distance between the opposite side surfaces and a width of two separate portions of the heat dissipation gel discharged in the side surface coating step.

9. The method according to claim 1, wherein, in the top surface coating step, the heat dissipation gel is discharged such that thickness of the heat dissipation gel at a position corresponding to a center of the electronic component becomes larger than at a position corresponding to both ends of the electronic component.
